(19) United States
(12) Patent Application Publication
(10) Pub. No.: US 2019/0043999 A1
(43) Pub. Date: Feb. 7, 2019

(54) SCHOTTKY DIODE

(71) Applicants: TOYOTA JIDOSHA KABUSHIKI KAISHA, Toyota-shi, Aichi-ken (JP); DENSO CORPORATION, Kariya-city, Aichi-pref (JP)

(72) Inventors: Tatsuji NAGAOKA, Nagakute-shi (JP); Sachiko AOI, Nagakute-shi (JP); Yasushi URAKAMI, Kariya-shi (JP)

(73) Assignees: TOYOTA JIDOSHA KABUSHIKI KAISHA, Toyota-shi, Aichi-ken (JP); DENSO CORPORATION, Kariya-city, Aichi-pref (JP)

(21) Appl. No.: 16/073,924

(22) PCT Filed: Jan. 31, 2017
(86) PCT No.: PCT/IB2017/000051

§ 371 Date: Jul. 30, 2018

(30) Foreign Application Priority Data
Feb. 2, 2016 (JP) 2016-018089

(51) Int. Cl. H01L 29/872; H01L 29/24; H01L 29/06; H01L 29/40

(52) U.S. Cl. CPC H01L 29/872; H01L 29/24; H01L 29/2003; H01L 29/402; H01L 29/408; H01L 29/0661

(57) ABSTRACT

A diode includes: a semiconductor substrate including a first surface including a first range and a second range surrounding the first range, the first surface of the semiconductor substrate protruding in the first range from the second range such that the first surface having a step along a border between the first range and the second range; a first electrode that is in Schottky contact with the first electrode within the first range; an interlayer insulating film that covers the step, the second range, and an end portion of the first electrode; and a field plate electrode conductively connected to the first electrode. The field plate electrode covers a region of the interlayer insulating film covering the end portion of the first electrode and a region of the interlayer insulating film covering the step, and extends onto a region of the interlayer insulating film covering the second range.

### BACKGROUND OF THE INVENTION

### 1. Field of the Invention

The present invention relates to a diode.

### 2. Description of Related Art

Japanese Patent Application Publication No. 2013-102081 (JP 2013-102081 A) discloses a Schottky barrier diode (whose abbreviation is an SBD) that is equipped with an anode electrode that is in contact with part of an upper surface of a semiconductor substrate, and a cathode electrode that is in contact with a lower surface of the semiconductor substrate. The upper surface of the semiconductor substrate has a first range, and a second range that surrounds the first range. The upper surface of the semiconductor substrate is high in the first range and low in the second range, and a step extends along a border between the first range and the second range. The anode electrode is in Schottky contact with the upper surface of the semiconductor substrate in the first range. The cathode electrode is in ohmic contact with the lower surface of the semiconductor substrate. By adopting a step structure as mentioned above (a so-called mesa structure) on the upper surface of the semiconductor substrate, an attempt is made to mitigate the convergence of electric field that is likely to occur in the vicinity of an end portion of the anode electrode and thus improve a reverse breakdown voltage.

Japanese Patent Application Publication No. 2013-102081 (JP 2013-102081 A) also suggests a concept of mitigating the convergence of electric field in the vicinity of the end portion of the anode electrode by further providing a field plate electrode that is connected to the anode electrode and that is opposed to the upper surface of the semiconductor substrate via an interlayer insulating film in the case where the semiconductor substrate does not have the aforementioned mesa structure.

Therefore, in the SBD having the aforementioned mesa structure, it is also conceivable to adopt various configurations that are further equipped with the field plate electrode that is connected to the anode electrode.

### SUMMARY OF THE INVENTION

However, even in the case where such a configuration is adopted, when the field plate electrode is arranged in a certain manner, it may be impossible to ensure a necessary reverse breakdown voltage due to an insufficient effect of mitigating the convergence of electric field in the vicinity of the end portion of the anode electrode.

The present invention provides a diode that can realize a high reverse breakdown voltage.

A diode according to an aspect of the invention includes: a semiconductor substrate including a first surface including a first range and a second range, the second range surrounding the first range, the first surface of the semiconductor substrate being further from a second surface of the semiconductor substrate in the first range than in the second range, and the first surface having a step in a thickness direction of the semiconductor substrate along a border between the first range and the second range; a first electrode that is in Schottky contact with the first surface of the semiconductor substrate in the first range, the first electrode being disposed within the first range; an interlayer insulating film that covers the step, the second range, and an end portion of the first electrode; and a field plate electrode conductively connected to the first electrode, the field plate electrode covering a region of the interlayer insulating film covering the end portion of the first electrode and a region of the interlayer insulating film covering the step, and the field plate electrode extending onto a region of the interlayer insulating film covering the second range; and a second electrode disposed on the second surface of the semiconductor substrate. In the aforementioned aspect of the invention, “the provision (of the upper surface electrode) in the first range” may include a case where the end portion of the upper surface electrode reaches the end portion of the first range, and a case where the end portion of the upper surface electrode is arranged on the first range at a position spaced apart from the end portion of the first range.

In the aforementioned diode, the field plate electrode covers that region of the interlayer insulating film which covers the end portion of the first electrode, and that region of the interlayer insulating film which covers the step, and extends onto that region of the interlayer insulating film which covers the second range. Therefore, when a reverse bias is applied, a depletion layer can also be extended into that region of the interlayer insulating film which is located above the step and the second range and that region of the semiconductor substrate which is located below the step and the second range. Therefore, the convergence of electric field in the vicinity of the end portion of the upper surface electrode can be sufficiently mitigated. In consequence, according to the aforementioned configuration, a high reverse breakdown voltage can be realized.

In the above aspect, the semiconductor substrate may include a layered structure of a first n-type layer and a second n-type layer having a lower concentration of n-type impurities than the first n-type layer. The second n-type layer may be exposed to the first range and the second range. A high-resistance region that has a lower concentration of n-type impurities than the second n-type layer may be disposed on a side closer to the first surface than the second n-type layer in a range from the end portion of the first range to the second range via the step.

The depletion layer is more likely to extend into the second n-type layer having a low concentration of n-type impurities than into the first n-type layer. Therefore, according to the aforementioned configuration, the depletion layer can be sufficiently extended into the second n-type layer when a reverse bias is applied thereto. Moreover, the depletion layer is more likely to extend into the high-resistance region having a lower concentration of n-type impurities than into the second n-type layer. Therefore, according to the aforementioned configuration, the convergence of electric field in the vicinity of the end portion of the first electrode can be sufficiently mitigated.

In the above aspect, the high-resistance region may reach the second n-type layer.

According to this configuration, the interval of the distribution of potentials (i.e., the interval among equipotential lines) in the depletion layer in the vicinity of the end portion of the first electrode is substantially constant, and changes in the potential in the vicinity of the end portion of the first electrode are unlikely to become irregular. Therefore, the convergence of electric field in the vicinity of the end portion of the first electrode can be sufficiently mitigated.

the high-resistance region may reach a lateral surface of the semiconductor substrate.

According to this configuration, the depletion layer can be formed to a position spaced apart from the end portion of the first electrode in the direction of the lateral surface of the semiconductor substrate.

In the above aspect; the field plate electrode may be provided in a range where the high-resistance region is provided in a plan view of the semiconductor substrate.

According to this configuration, the convergence of electric field in the vicinity of the extension of the field plate electrode can also be sufficiently mitigated.

In the above aspect, the end portion of the first electrode may be spaced apart from the end portion of the first range in a cross-sectional view of the semiconductor substrate in the thickness direction.

In the above aspect, a specific permittivity of the high-resistance region may be larger than a specific permittivity of the first electrode, and may be smaller than a specific permittivity of the interlayer insulating film.

In the above aspect, the first electrode may include a Schottky electrode film and a layered electrode film. The Schottky electrode film may be in contact with the first surface of the semiconductor substrate in the first range. The interlayer insulating film may cover an end portion of the Schottky electrode film. The layered electrode film may be layered on a portion of the Schottky electrode film, which is not covered with the interlayer insulating film. The layered electrode film may be continuous to the field plate electrode.

According to this configuration, in manufacturing the diode, the interlayer insulating film can be formed after the Schottky electrode film is formed on the first range of the first surface of the semiconductor substrate. Therefore, the Schottky electrode film can be formed while the first surface of the semiconductor substrate is clean. As a result, a stable Schottky interface can be obtained.

In the above aspect, the interlayer insulating film may be in contact with the end portion of the first electrode and the step and the second range of the first surface, and the field plate electrode may be in contact with a region of the interlayer insulating film which contacts and covers the end portion of the first electrode and the step, and part of a region of the interlayer insulating film which covers the second range.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a cross-sectional view of an SBD 2 according to the first embodiment of the invention;

FIG. 2 is a view showing a state where a reverse bias is applied to the SBD 2 of FIG. 1;

FIG. 3 is a cross-sectional view of an SBD 102 according to the second embodiment of the invention;

FIG. 4 is a view showing a state where a reverse bias is applied to the SBD 102 of FIG. 3;

FIG. 5 is a cross-sectional view of an SBD 202 according to the third embodiment of the invention; and

FIG. 6 is a view showing a state where a reverse bias is applied to the SBD 202 of FIG. 5.

### DETAILED DESCRIPTION OF EMBODIMENTS

### First Embodiment

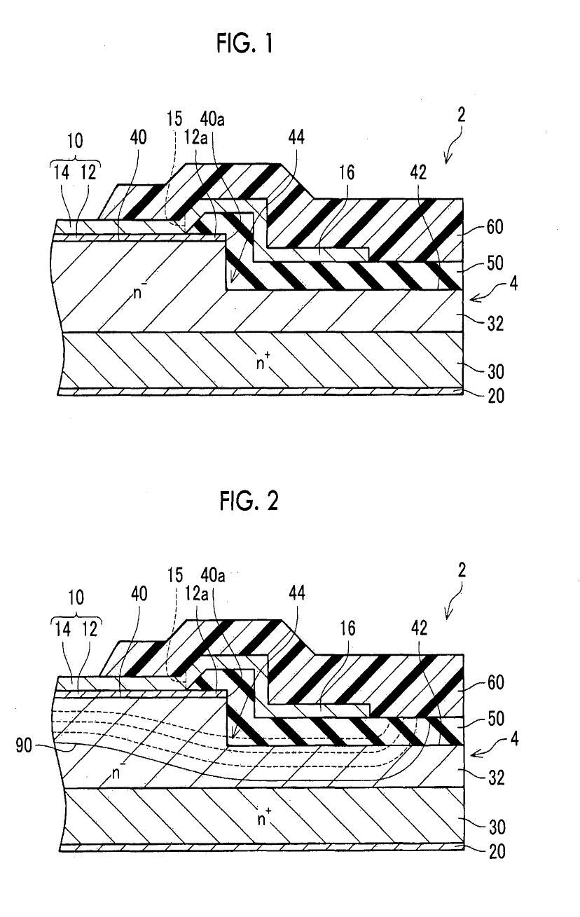

As shown in FIG. 1, the SBD 2 according to the present embodiment of the invention has a semiconductor substrate 4, an upper surface electrode 10, a field plate electrode 16, an interlayer insulating film 50, a protection film 60 and a lower surface electrode 20.

The semiconductor substrate 4 is a n-type semiconductor substrate that is formed of Ga₂O₃. The semiconductor substrate 4 has a lower layer 30 having a high concentration of n-type impurities, and an upper layer 32 having a lower concentration of n-type impurities than the lower layer 30. The upper layer 32 is layered on the lower layer 30. The concentration of impurities mentioned herein means an average concentration of impurities in each of the layers. The upper layer 32 functions as a drift layer of the SBD 2. An upper surface of the upper layer 32 is exposed to an upper surface of the semiconductor substrate 4, and a lower surface of the lower layer 30 is exposed to a lower surface of the semiconductor substrate 4.

The upper surface of the semiconductor substrate 4 has a so-called mesa structure. In concrete terms, the upper surface of the semiconductor substrate 4 is equipped with a first range 40, and a second range 42 that surrounds the first range 40. The upper surface of the semiconductor substrate 4 is high in the first range 40 and low in the second range 42. Besides, a step 44 extends along a border between the first range 40 and the second range 42.

The upper surface electrode 10 has a Schottky electrode film 12 and a layered electrode film 14. The Schottky electrode film 12 is in Schottky contact with an entire surface of the first range 40 of the upper surface of the semiconductor substrate 4. The Schottky electrode film 12 remains in the first range 40, and does not extend onto the second range 42. An end portion 12a of the Schottky electrode film 12 reaches an end portion 40a of the first range 40. Besides, the layered electrode film 14 is layered on that region of an upper surface of the Schottky electrode film 12 which does not include the end portion 12a that is covered with the interlayer insulating film 50, and is continuous to the field plate electrode 16. A borderline 15 in the drawing virtually indicates a border between the layered electrode film 14 and the field plate electrode 16. The upper surface electrode 10 functions as an anode electrode of the SBD 2.

The interlayer insulating film 50 is an insulating film that covers the end portion 12a of the Schottky electrode film 12, the step 44 and the second range 42. The interlayer insulating film 50 is provided in contact with the end portion 12a of the Schottky electrode film 12 and the step 44 and the second range 42 of the upper surface of the semiconductor substrate 4, and covers the end portion 12a of the Schottky electrode film 12, and the step 44 and the second range 42 of the upper surface of the semiconductor substrate 4. The interlayer insulating film 50 is formed of ZrO₂. In other examples, the interlayer insulating film 50 may be formed of HfO₂. The specific permittivity of the interlayer insulating film 50 is larger than the specific permittivity of SiO₂, and is larger than the specific permittivity of the upper layer 32.

The field plate electrode 16 is formed continuously to the layered electrode film 14. The field plate electrode 16 is formed in such a manner as to cover that region of the interlayer insulating film 50 which covers the end portion 12a of the Schottky electrode film 12 and that region of the interlayer insulating film 50 which covers the step 44, and extends to an upper side of that region of the interlayer insulating film 50 which covers the second range 42. That is, the field plate electrode 16 is formed on that region of the interlayer insulating film 50 which is provided on the end portion 12a of the Schottky electrode film 12 and that region of the interlayer insulating film 50 which is provided on the step 44, and extends to the upper side of that region of the interlayer insulating film 50 which is provided on the second range 42.

In the present embodiment of the invention, a junction interface between the first range 40 of the upper surface of the semiconductor substrate 4 and the Schottky electrode film 12 is higher than an interface between that region of the field plate electrode 16 which covers the interlayer insulating film 50 on the second range 42 and that region of the interlayer insulating film 50 which is on the second range 42.

The protection film 60 is an insulating film that covers part of the upper surface electrode 10, the field plate electrode 16 and part of the interlayer insulating film 50. The protection film 60 is formed of polyimide.

The lower surface electrode 20 is in ohmic contact with the lower surface of the lower layer 30. The lower surface electrode 20 functions as a cathode electrode of the SBD 2. In the present embodiment of the invention, the lower surface electrode 20 is in contact with an entire area of the lower surface of the lower layer 30. In a modification example, however, the lower surface electrode 20 may be in contact with part of the lower surface of the semiconductor substrate 4.

Next, the operation of the SBD 2 according to the present embodiment of the invention will be described. When a voltage making the upper surface electrode 10 plus (i.e., a forward bias) is applied between the upper surface electrode 10 and the lower surface electrode 20, electrons move from the semiconductor substrate 4 side toward the upper surface electrode 10. Thus, a current flows from the upper surface electrode 10 to the lower surface electrode 20.

Besides, when a voltage making the lower surface electrode 20 plus (i.e., a reverse bias) is applied between the upper surface electrode 10 and the lower surface electrode 20, a depletion layer 90 that extends into the semiconductor substrate 4 and the interlayer insulating film 50 is formed as shown in FIG. 2. In the semiconductor substrate 4, the depletion layer 90 extends into the upper layer 32 having a low concentration of n-type impurities, but does not extend into the lower layer 30 having a high concentration of n-type impurities. Incidentally, FIG. 2 virtually shows equipotential lines indicating the distribution of potentials in the depletion layer 90 (see broken lines in the drawing).

In the present embodiment of the invention, the field plate electrode 16 that continues to the layered electrode film 14 is provided, so the depletion layer 90 extends to a position spaced laterally apart from an end portion of the upper surface electrode 10 (i.e., the end portion 12a of the Schottky electrode film 12). Besides, in the present embodiment of the invention, the upper surface of the upper layer 32 of the semiconductor substrate 4 has the aforementioned mesa structure. Furthermore, the field plate electrode 16 is formed in such a manner as to cover that region of the interlayer insulating film 50 which covers the end portion 12a of the Schottky electrode film 12 and that region of the interlayer insulating film 50 which covers the step 44, and extends to the upper side of that region of the interlayer insulating film 50 which covers the second range 42. Therefore, the depletion layer 90 can also be extended into that region of the interlayer insulating film 50 which is located above the step 44 and the second range 42 and that region of the upper layer 32 which is located below the step 44 and the second range 42. As a result, the convergence of electric field in the vicinity of the end portion 12a of the Schottky electrode film 12 can be sufficiently mitigated. Therefore, the SBD 2 according to the present embodiment of the invention makes it possible to realize a high reverse breakdown voltage.

Besides, as described above, in the present embodiment of the invention, the upper surface electrode 10 has a structure in which the Schottky electrode film 12 and the layered electrode film 14 are layered on each other. The end portion 12a of the Schottky electrode film 12 is covered with the interlayer insulating film 50. Therefore, in manufacturing the SBD 2, the interlayer insulating film 50 can be formed after the Schottky electrode film 12 is formed on the first range 40 of the upper surface of the semiconductor substrate 4. Therefore, the Schottky electrode film 12 can be formed while the upper surface of the semiconductor substrate 4 is clean, so a stable Schottky interface can be obtained.

### Second Embodiment

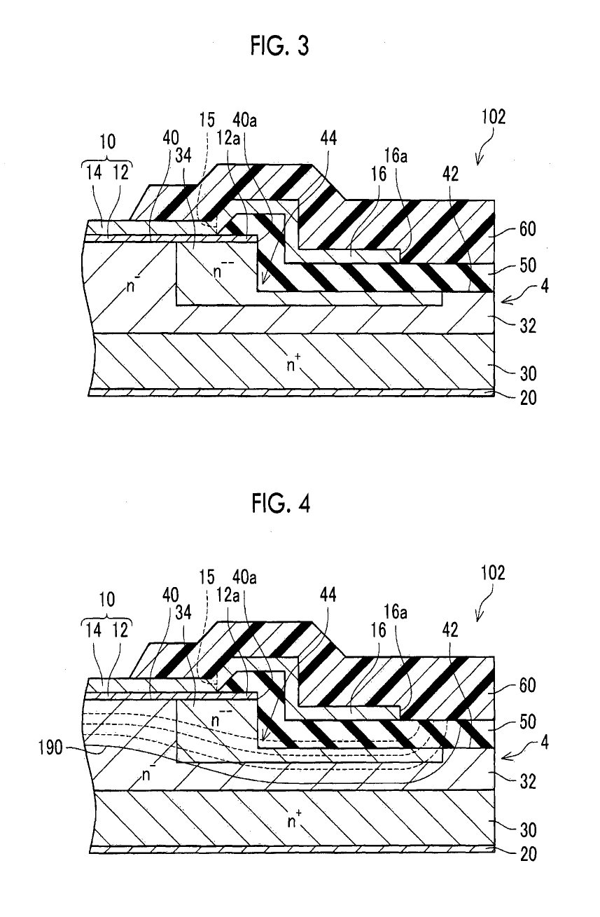

Subsequently, the SBD 102 according to the second embodiment of the invention will be described with reference to FIGS. 3 and 4, focusing on what is different from the first embodiment of the invention. In FIGS. 3 and 4, elements identical or similar to those of the SBD 2 according to the first embodiment of the invention are denoted by the same reference symbols respectively, and detailed description thereof will be omitted. The SBD 102 according to the present embodiment of the invention is different from the SBD according to the first embodiment of the invention in that a high-resistance region 34 is formed in the upper layer 32.

The high-resistance region 34 is an n-type region that is formed on the upper surface side of the upper layer 32 in a range from the end portion 40a of the first range 40 to the second range 42 via the step 44. In the present embodiment of the invention, a lower surface of the high-resistance region 34 is spaced apart from the lower layer 30. The concentration of n-type impurities in the high-resistance region 34 is lower than the concentration of n-type impurities in the upper layer 32. Besides, the specific permittivity of the high-resistance region 34 is larger than the specific permittivity of the upper layer 32, and is smaller than the specific permittivity of the interlayer insulating film 50. Besides, an extension 16a of the field plate electrode 16 remains on a range of formation of the high-resistance region 34. Besides, in a modification example, the high-resistance region 34 may be a so-called i-type region that is formed without carrying out a treatment of adding impurities.

Next, the operation of the SBD 102 according to the present embodiment of the invention will be described. The operation in the case where a forward bias is applied to the SBD 102 is identical to the operation in the case of the SBD 2 according to the first embodiment of the invention, so description thereof will be omitted. On the other hand, when a reverse bias is applied to the SBD 102, a depletion layer 190 that extends into the semiconductor substrate 4 and the interlayer insulating film 50 is formed as shown in FIG. 4. As described above, in the present embodiment of the invention, the high-resistance region 34 is provided in the upper layer 32. The concentration of n-type impurities in the high-resistance region 34 is lower than the concentration of n-type impurities in the upper layer 32, so the depletion layer is more likely to extend into the high-resistance region 34 than into the upper layer 32. Therefore, according to the configuration of the present embodiment of the invention, the convergence of electric field in the vicinity of the end portion 12a of the Schottky electrode film 12 can be further mitigated. Besides, as described above, the extension 16a of the field plate electrode 16 remains on the range of formation of the high-resistance region 34. Therefore, the convergence of electric field in the vicinity of the extension 16a of the field plate electrode 16 can also be sufficiently mitigated.

### Third Embodiment

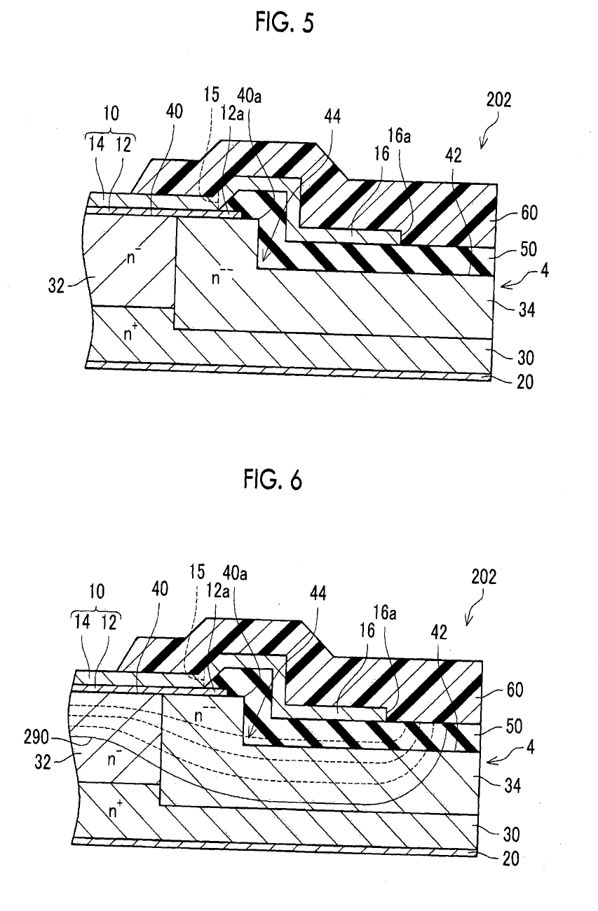

Subsequently, the SBD 202 according to the third embodiment of the invention will be described with reference to FIGS. 5 and 6, focusing on what is different from the second embodiment of the invention. In FIGS. 5 and 6, elements identical or similar to those of the SBD 2 or 102 according to each of the aforementioned embodiments of the invention are denoted by the same reference symbols respectively, and detailed description thereof will be omitted. The SBD 202 according to the present embodiment of the invention is different from the SBD according to the second embodiment of the invention in that the lower surface of the high-resistance region 34 reaches the lower layer 30, that the high-resistance region 34 reaches a lateral surface of the semiconductor substrate 4, and that the end portion 12a of the Schottky electrode film 12 is arranged at a position spaced apart from the end portion 40a of the first range 40. It should be noted herein that the lateral surface of the semiconductor substrate 4 may be regarded as that one of surfaces of the semiconductor substrate 4 which stretches in a thickness direction of the semiconductor substrate 4 between an edge portion of the upper surface and an edge portion of the lower surface.

Subsequently, the operation of the SBD 202 according to the present embodiment of the invention will be described. The operation in the case where a forward bias is applied to the SBD 202 is also identical to the operation in the case of the SBD 2 or 102 according to each of the aforementioned first and second embodiments of the invention, so detailed description thereof will be omitted. On the other hand, when a reverse bias is applied to the SBD 202, a depletion layer 290 that extends into the semiconductor substrate 4 and the interlayer insulating film 50 is, formed as shown in FIG. 6. In the present embodiment of the invention, as described above, the lower surface of the high-resistance region 34 reaches the lower layer 30. Therefore, the interval among equipotential lines in the depletion layer 290 in the vicinity of the end portion 12a of the Schottky electrode film 12 is substantially constant, and changes in the potential in the vicinity of the end portion 12a of the Schottky electrode film 12 are unlikely to become irregular. Therefore, the convergence of electric field in the vicinity of the end portion 12a of the Schottky electrode film 12 can be sufficiently mitigated. Besides, in the present embodiment of the invention, the arrangement of the end portion 12a of the Schottky electrode film 12 at a position spaced apart from the end portion 40a of the first range 40 also contributes toward mitigating the convergence of electric field in the vicinity of the end portion 12a of the Schottky electrode film 12. Furthermore, in the present embodiment of the invention, the high-resistance region 34 reaches the lateral surface of the semiconductor substrate 4. Therefore, the depletion layer 290 can be formed to a position spaced apart from the end portion 12a of the Schottky electrode film 12 and the extension 16a of the field plate electrode 16.

The concrete examples of the art disclosed in the present specification have been described above in detail. However, these concrete examples are nothing more than exemplifications, and do not limit the invention. The art of the invention includes various modifications and alterations of the concrete examples exemplified above within such a range as not to depart from the gist of the invention. For example, the following modification examples may be adopted.

### First Modification Example

The upper surface electrode 10 may be obtained by forming the Schottky electrode film 12 and the layered electrode film 14 integrally with each other.

### Second Modification Example

The semiconductor substrate 4 may be formed of a material other than Ga₂O₃, such as GaN, Si, SiC or the like. In particular, in the modification example in which the semiconductor substrate 4 is formed of Si or SiC, a thermal oxidation film may be further formed between the interlayer insulating film 50 and the upper layer 32.

The technical elements described in the present specification or the drawings are technically useful alone or in various combinations, and are not limited to the combination described in the present specification. Besides, the art exemplified in the present specification or the drawings achieves a plurality of objects at the same time, and is technically useful by achieving one of the objects alone.

1. A diode comprising:
a semiconductor substrate including a first surface including a first range and a second range, the second range surrounding the first range, the first surface of the semiconductor substrate being further from a second surface of the semiconductor substrate in the first range than in the second range, and the first surface having a step in a thickness direction of the semiconductor substrate along a border between the first range and the second range;
a first electrode that is in Schottky contact with the first surface of the semiconductor substrate in the first range, the first electrode being disposed within the first range;
an interlayer insulating film that covers the step, the second range, and an end portion of the first electrode; and
a field plate electrode conductively connected to the first electrode, the field plate electrode covering a region of the interlayer insulating film covering the end portion of the first electrode and a region of the interlayer insulating film covering the step, and the field plate electrode extending onto a region of the interlayer insulating film covering the second range; and
a second electrode disposed on the second surface of the semiconductor substrate.

2. The diode according to claim 1, wherein
the semiconductor substrate includes a layered structure of a first n-type layer and a second n-type layer having a lower concentration of n-type impurities than the first n-type layer,
the second n-type layer is exposed to the first range and the second range, and
a high-resistance region that has a lower concentration of n-type impurities than the second n-type layer is disposed on a side closer to the first surface than the second n-type layer in a range from the end portion of the first range to the second range via the step.

3. The diode according to claim 2, wherein
the high-resistance region reaches the second n-type layer.

4. The diode according to claim 2, wherein
the high-resistance region reaches a lateral surface of the semiconductor substrate.

5. The diode according to claim 2, wherein
the field plate electrode is provided in a range where the high-resistance region is provided in a plan view of the semiconductor substrate.

6. The diode according to claim 1, wherein
the end portion of the first electrode is spaced apart from the end portion of the first range in a cross-sectional view of the semiconductor substrate in the thickness direction.

7. The diode according to claim 2, wherein
a specific permittivity of the high-resistance region is larger than a specific permittivity of the first electrode, and is smaller than a specific permittivity of the interlayer insulating film.

8. The diode according to claim 1, wherein
the first electrode includes a Schottky electrode film and a layered electrode film,
the Schottky electrode film is in contact with the first surface of the semiconductor substrate in the first range,
the interlayer insulating film covers an end portion of the Schottky electrode film,
the layered electrode film is layered on a portion of the Schottky electrode film, which is not covered with the interlayer insulating film, and
the layered electrode film is continuous to the field plate electrode.

9. The diode according to claim 1, wherein
the interlayer insulating film is in contact with the end portion of the first electrode and the step and the second range of the first surface, and
the field plate electrode is in contact with a region of the interlayer insulating film which contacts and covers the end portion of the first electrode and the step, and part of a region of the interlayer insulating film which covers the second range.
